(19) United States
(12) Patent Application Publication
(10) Pub. No.: US 2009/0095338 A1
(43) Pub. Date: Apr. 16, 2009

(54) SOLAR POWER SOURCE

(76) Inventors: James Chyl Lai, Saint Paul, MN (US); Tom Allen AGAN, Saint Paul, MN (US); Chung Ping Lai, Saint Paul, MN (US)

Correspondence Address: PATTERSON & SHERIDAN, L.L.P., 3040 POST OAK BOULEVARD, SUITE 1500, HOUSTON, TX, 77056, US

(21) Appl. No.: 11/871,009

(22) Filed: Oct. 11, 2007

(51) Int. Cl. H01L 31/042

(52) U.S. Cl. 136/244

(57) ABSTRACT

A solar power source includes a solar panel and a magnetic capacitor. The solar panel receives solar energy, and the magnetic capacitor stores energy and provides electricity. The solar panel has a first side facing the sun, and the magnetic capacitor is attached to a second side of the solar panel. The magnetic capacitor has high valued storage capacitance to handle the charge generated by the solar panel, and has a barrier to leakage current, so that storage time is increased. The solar power source is applicable for many applications and has low energy transport costs. The solar power source may have a higher number of re-charging cycles compared to batteries, and may be partially charged or discharged without a reduction in charge capacity. Two methods of manufacturing the solar power source are also provided.

### BACKGROUND OF THE INVENTION

1. Field of the Invention

The present invention relates to a solar power source. More particularly, the present invention relates to a solar power source with a magnetic capacitor.

2. Description of Related Art

Solar power can be a good replacement for the diminishing sources of conventional energy. Different developments of solar technology have been available. Some solar systems use a grid, but the energy may be generated hundreds of miles away from the place it gets used. There is significant loss of energy in the transportation.

Another type of power source providing power to a system such as any electronic device is a battery. A battery provides a constant voltage to the electronic device so that the electronic device may be powered by a stable power source. However, the use of batteries as power sources for electronic devices suffer from a couple of problems. First, a re-chargeable battery has a limited number of re-chargings, and as the battery is re-charged towards that limit, the capacity of the battery will start to decrease. Second, a battery has a memory problem. If the battery is only partially charged or charged before the complete depletion of energy, then the capacity of the battery may decrease.

For the forgoing reasons, there is a need for a new type of solar power source, so that it has low energy transport costs, and can be an alternative to a battery while overcoming the problems stated above.

### SUMMARY OF THE INVENTION

The present invention is directed to a solar power source that satisfies this need of having low energy transport costs, having a higher number of re-chargings and being partially charged or discharged without degradation in capacity.

It is therefore an objective of the present invention to provide a solar power source that can capture the sunlight, store the energy, and provide electricity on demand.

It is another objective of the present invention to provide a solar power source that can be served as a battery with a higher number of re-chargings and can be partially charged or discharged between each recharging without loss of performance.

It is still another objective of the present invention provide a solar power source that has very low energy transport costs because the energy can be obtained close to where it is being used.

It is still another objective of the present invention to provide two methods of manufacturing the solar power source.

A solar power source includes a solar panel and a magnetic capacitor. The solar panel receives solar energy, and the magnetic capacitor stores solar energy and provides electricity. The solar panel has a first side facing the sun, and the magnetic capacitor is attached to a second side of the solar panel. The magnetic capacitor has high valued storage capacitance to handle the charge generated by the solar panel, and has a barrier to leakage current, so that storage time is increased.

The solar power source is applicable for many applications and particularly for portable appliances. When connecting an appliance to a power grid is not available, the solar power source can provide electricity to the appliance.

Two methods of manufacturing the solar power source are also provided. The first method of manufacturing the solar power source includes forming a solar panel and then forming a magnetic capacitor on top of the solar panel.

The second method of manufacturing the solar power source includes forming a solar panel, forming a magnetic capacitor, joining the solar panel and the magnetic capacitor by abutment, placing a first wire in between a second side of the solar panel and a third side of the magnetic capacitor, and attaching a second wire to a first side of the solar panel and a forth side of the magnetic capacitor.

The solar panel and the magnetic capacitor are manufactured on semiconductor manufacturing equipment, and a higher temperature is used when forming the solar panel. The magnetic capacitor has high valued storage capacitance to handle charge generated by the solar panel and has a barrier to leakage current, so that its storage time is increased.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a side cross-sectional view showing the structure of the solar power source according to an embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

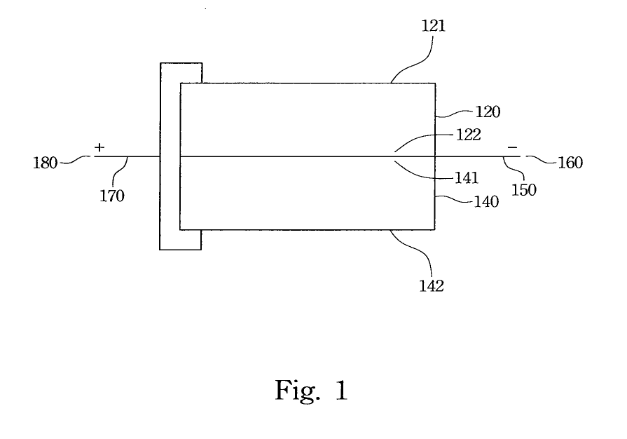

Please refer to FIG. 1, a side cross-sectional view showing the structure of the solar power source according to an embodiment of the present invention. The solar power source includes a solar panel 120 and a magnetic capacitor 140. The solar panel 120 receives solar energy from sunlight, and the magnetic capacitor 140 stores the solar energy and provides electricity to electronic devices when it is needed. The solar panel 120 has a first side 121 and a second side 122, and the magnetic capacitor 140 has a third side 141 and a forth side 142. The first side of the solar panel 121 faces the sun, and the third side of the magnetic capacitor 141 is attached to the second side of the solar panel 122. The forth side of the magnetic capacitor 142 is away from the sunlight. A first wire 150 is placed between the second side of the solar panel 122 and the third side of the magnetic capacitor 141. The second wire 170 is attached to the first side of the solar panel 121 and a forth side of the magnetic capacitor 142. The end of the first wire 150 can be an anode 160, while the end of the second wire 170 can be a cathode 180.

A method of manufacturing the solar power source includes the following steps: forming the solar panel 120 having a first side 121 and a second side 122; forming the magnetic capacitor 140 having a third side 141 and a forth side 142; joining the solar panel 120 and the magnetic capacitor 140 by abutment; placing a first wire 150 in between the second side of the solar panel 122 and the third side of the magnetic capacitor 141; and attaching a second wire 170 to the first side of the solar panel 121 and the forth side of the magnetic capacitor 142. The end of the first wire 150 forms an anode 160, while the end of the second wire 170 forms a cathode 180. The solar panel 120 and the magnetic capacitor 140 are both manufactured on semiconductor manufacturing equipment. The solar panel 120 is formed with a high temperature, whereas the magnetic capacitor 140 is formed with a lower temperature. The solar panel 120 and the magnetic capacitor 140 are manufactured separately, and the yields would be higher. With metal on the second side of the solar panel 122, and metal on the third side of the magnetic capacitor 141, it is easy to connect both and complete the circuit.

There are two reasons why the magnetic capacitor 140 can be used with the solar panel 120 to store solar energy. First, the magnetic capacitor 140 has high valued storage capacitance to handle the charge generated by the solar panel 120. Second, the magnetic capacitor 140 has a barrier to leakage current, so that the storage time of the energy is greatly increased.

Capacitors were not used to store solar energy because they did not have the storage capability to handle the large amount of charge generated by the solar panels in full sunlight. Typically, one day of sunlight, in average, represents about five hours of peak radiation. If the charge current density provided to a capacitor designed for storing the generated solar energy is 3.3 mA/cm², the total charge to be stored would be 3.3×10⁻³×18000(second)=59.4 C/cm². If this capacitor is to achieve a maximum voltage of 0.45 V, the capacitance should be 59.4/0.45=132 F/cm². Furthermore, for a commercial solar cell with conversion efficiency around 15%, this capacitance would become 3142 F/cm² without taking into account the charge-discharge efficiency. With magnetic capacitors, that capacitance is possible. With many reports of 10⁹ increases, capacitance is expected to be over 5000 F/cm². So, the magnetic capacitor can handle the large amount of charge generated by the solar panel.

Another reason that capacitors were not used to store solar energy is because of the leakage current. However, magnetic capacitors have a barrier to leakage current because the magnetic layers prevents current of either spin up or spin down from passing. This means the storage time is greatly increased.

The solar power source can be used in a great many applications and is particularly applicable for portable appliances. The solar power source provides electricity to an appliance when connecting the appliance to a power grid is not available.

The solar power source can be served as a battery with a much higher number of re-chargings compared to chemical batteries, and can be partially charged or discharged between each re-charging without loss of performance.

Moreover, the solar power source is more efficient because there is very low energy transport costs. The solar energy is stored in the magnetic capacitor adjacent to the solar panel, so the energy can be used close to where it is obtained. Compare to the grid where the energy may be generated hundreds of miles away from the place it gets used, there is significant loss of energy in the transportation.

Although the present invention has been described in considerable detail with reference to certain preferred embodiments thereof, other embodiments are possible. For example, if the solar panel and the magnetic capacitor are manufactured in the same process flow, the solar panel will be formed with a higher temperature, and the magnetic capacitor will be formed later. The process is similar to the typical semiconductor manufacturing method where the transistors are put down first, and metal routing later. Then, this solar power source will simply be turned over so that the solar panel will face the sun and the magnetic capacitor will be away from the sun. Therefore, the spirit and scope of the appended claims should not be limited to the description of the preferred embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A solar power source, comprising:
a solar panel for receiving solar energy; and
a magnetic capacitor for storing solar energy and providing electricity;
wherein the solar panel has a first side facing the sun, and the magnetic capacitor is attached to a second side of the solar panel.

2. The solar power source of claim 1, wherein the solar power source is applicable for a portable appliance.

3. The solar power source of claim 1, wherein the solar power source provides electricity to an appliance when connecting the appliance to a power grid is not available.

4. The solar power source of claim 1, wherein charge capacity of the solar power source is maintained when the solar power source is partially charged or discharged between each recharging.

5. The solar power source of claim 1, wherein the solar power source has a higher number of re-chargings compared to a chemical battery.

6. The solar power source of claim 1, wherein the magnetic capacitor has high valued storage capacitance to handle charge generated by the solar panel.

7. The solar power source of claim 1, wherein the magnetic capacitor has a barrier to leakage current, so that storage time is increased.

8. A method of manufacturing a solar power source, comprising the steps of:
forming a solar panel; and
forming a magnetic capacitor on top of the solar panel.

9. The method of claim 8, wherein the solar panel and the magnetic capacitor are manufactured on semiconductor manufacturing equipment, and a higher temperature is used when forming the solar panel.

10. The method of claim 8, wherein the magnetic capacitor has high valued storage capacitance to handle charge generated by the solar panel.

11. The method of claim 8, wherein the magnetic capacitor has a barrier to leakage current, so that storage time is increased.

12. A method of manufacturing a solar power source, comprising the steps of:
forming a solar panel having a first side and a second side;
forming a magnetic capacitor having a third side and a forth side;
joining the solar panel and the magnetic capacitor by abutment;
placing a first wire in between the second side of the solar panel and the third side of the magnetic capacitor; and
attaching a second wire to the first side of the solar panel and the forth side of the magnetic capacitor.

13. The method of claim 12, wherein the solar panel and the magnetic capacitor are manufactured on semiconductor manufacturing equipment, and a higher temperature is used when forming the solar panel.

14. The method of claim 12, wherein the magnetic capacitor has high valued storage capacitance to handle charge generated by the solar panel.

15. The method of claim 12, wherein the magnetic capacitor has a barrier to leakage current, so that storage time is increased.

16. The method of claim 12, wherein the first wire forms an anode, and the second wire forms a cathode.
